(19) United States
(12) Patent Application Publication
(10) Pub. No.: US 2016/0293084 A1
(43) Pub. Date: Oct. 6, 2016

(54) PIXEL STRUCTURE, METHOD FOR DRIVING PIXEL STRUCTURE AND DISPLAY APPARATUS

(71) Applicants: BOE Technology Group Co., Ltd., Beijing (CN); Beijing BOE Optoelectronics Technology Co., Ltd., Beijing (CN)

(72) Inventors: Renwei Guo, Beijing (CN); Xue Dong, Beijing (CN)

(21) Appl. No.: 14/814,689

(22) Filed: Jul. 31, 2015

(30) Foreign Application Priority Data
Mar. 31, 2015 (CN) 201510149457.3

(51) Int. Cl. G09G 3/20; H01L 27/32; G09G 3/32

(52) U.S. Cl. CPC G09G 3/2003; G09G 3/3208; H01L 27/3218; G09G 2300/0452

(57) ABSTRACT

Embodiments of the disclosure provide a pixel structure, a method for driving the pixel structure and a display apparatus. The pixel structure comprises a matrix of multiple R sub-pixels, G sub-pixels and B sub-pixels. In each row of the sub-pixels, at most two adjacent sub-pixels constitute a square pixel unit. Each two adjacent rows of the sub-pixels are offset relative to each other by half a sub-pixel along a row direction. Each of the sub-pixels is different in color from its adjacent sub-pixels. With such a pixel structure, light is reallocated for input information based on a correspondence relationship between an actual physical position and its corresponding input information so as to emit light concentratedly at the actual physical position. For example, a white pixel may be displayed by switching on only three adjacent sub-pixels triangularly arranged at the pixel unit which displays the white to be switched on. According to the embodiments of the disclosure, the same information is displayed with fewer pixels by selectively switching on sub-pixels in a flexible manner without reducing the size of pixels, thereby increasing the output resolution for displayed images.

This application claims priority from CN Patent Application No. 201510149457.3, filed on Mar. 31, 2015, which is incorporated herein by reference in its entirety.

### TECHNICAL FIELD

The disclosure generally relates to the technical field of displaying, more particularly, to a pixel structure, a method for driving the pixel structure and a display apparatus.

### BACKGROUND

Currently, RGB or RGBW designs are commonly used for display screens. In these designs, a displayed pixel consists of three or four sub-pixels and the visual resolution is the same as the physical resolution. With users' increasing demands on their experience with display screens, panel manufactures need to continuously increase the visual resolution of display screens, which is measured in terms of Pixels Per Inch (PPI). Currently, a physical resolution of display screens is increased typically by reducing the size of pixels. However, as the pixel gets smaller, the manufacturing process of display screens gets more difficult. This is especially true for the process of manufacturing Organic Light Emitting Diode (OLED) display screens, which involves a difficult patterning process of organics. Thus, there is a bottleneck for manufacturing display screens with higher physical resolution.

Therefore, it is desired to improve the visual resolution of display screens without reducing the size of pixels.

### SUMMARY

Embodiments of the disclosure disclose a pixel structure, a method for driving the pixel structure and a display apparatus to improve the visual resolution of display panels.

An embodiment of the disclosure provides a pixel structure comprising a matrix of multiple R sub-pixels, G sub-pixels and B sub-pixels,

in each row of the sub-pixels, at most two adjacent sub-pixels constitute a square pixel unit,

each two adjacent rows of the sub-pixels are offset relative to each other by half a sub-pixel along a row direction,

each of the sub-pixels is different in color from its adjacent sub-pixels.

Preferably, in each row of the sub-pixels,

each two sub-pixels constitute a square pixel unit and each sub-pixel has a length-width ratio of 2:1,

each one and a half sub-pixels constitute a square pixel unit and each sub-pixel has a length-width ratio of 3:2, or

each one sub-pixel constitutes a square pixel unit and each sub-pixel has a length-width ratio of 1:1.

An embodiment of the disclosure provides a display apparatus comprising the above-described pixel structure according to the embodiment of the disclosure.

An embodiment of the disclosure provides a method for driving the above-described pixel structure according to the embodiment of the disclosure. The method comprises:

when receiving an image signal for displaying at least a white pixel, switching on three adjacent sub-pixels triangularly arranged at a pixel unit which displays the white pixel in the pixel structure.

Preferably, in the above-described driving method according to the embodiment of the disclosure, when an image signal for displaying at least a row or column of white pixels is received, three adjacent sub-pixels triangularly arranged at each of pixel units in the pixel structure which display the row or column of white pixels are switched on.

Preferably, the above-described driving method according to the embodiment of the disclosure further comprises:

switching on three adjacent sub-pixels triangularly arranged at one or two rows or columns of pixel units in the pixel structure, the one or two rows or columns of pixel units are adjacent to the pixel units which display the row or the column of white pixels.

Preferably, in the above-described driving method according to the embodiment of the disclosure, when an image signal for displaying at least a pixel of a single color is received, a sub-pixel of the same color at a pixel unit in the pixel structure which displays the pixel of the single color is switched on.

Preferably, in the above-described driving method according to the embodiment of the disclosure, when an image signal for displaying at least a row or column of pixels of a single color is received, a sub-pixel of the same color at each of pixel units in the pixel structure which display the row or column of pixels of the single color is switched on.

Preferably, the above-described driving method according to the embodiment of the disclosure further comprises:

switching on a sub-pixel of the same color at each of one or two rows or columns of pixel units in the pixel structure which are adjacent to the pixel units that display the row or the column of pixels of the single color.

Preferably, in the above-described driving method according to the embodiment of the disclosure, when an image signal for displaying at least an oblique line of pixels of a single color is received, a sub-pixel of the same color at each of pixel units in the pixel structure which display the oblique line of pixels of the single color is switched on, and a sub-pixel of the same color at each of one or two oblique lines of pixel units in the pixel structure which are parallel to and adjacent to the oblique line of the single color on one or both sides is switched on.

According to embodiments of the disclosure, the pixel structure comprises a matrix of multiple R sub-pixels, G sub-pixels and B sub-pixels. In each row of the sub-pixels, at most two adjacent sub-pixels constitute a square pixel unit. Each two adjacent rows of the sub-pixels are offset relative to each other by half a sub-pixel along a row direction. Each of the sub-pixels is different in color from its adjacent sub-pixels. With such a pixel structure having an anisotropic pixel arrangement, it is possible to realize virtual displaying based on virtual calculation, that is, it is possible to reallocate light for input information based on an actual physical position and its corresponding input information so as to emit light concentratedly at the actual physical position. For example, when an image signal for displaying a white pixel is received, three adjacent sub-pixels triangularly arranged at a pixel unit in the pixel structure which displays the white pixel are switched on to display the white pixel. As compared with the conventional pixel structure which requires two adjacent groups of RGB sub-pixels in two adjacent rows at a pixel unit which displays a white pixel to be switched on when the white pixel is to be displayed, the pixel structure according to the embodiment of the disclosure requires only three adjacent sub-pixels triangularly arranged at the pixel unit which displays the white to be switched on. As such, it is possible to display the same information with fewer pixels by selectively switching on sub-pixels in a flexible manner without reducing the size of pixels, thereby increasing the output resolution for displayed images.

### BRIEF DESCRIPTION OF THE DRAWINGS

FIGS. 1-3 are diagrams respectively illustrating pixel structures according to embodiments of the disclosure;

FIG. 4a-4f are diagrams respectively illustrating periodic arrangements of sub-pixels according to embodiments of the disclosure;

FIG. 5 is a diagram illustrating how to switch on corresponding sub-pixels when a white pixel is displayed according to an embodiment of the disclosure;

FIG. 6 is a diagram illustrating a conventional method of switching on corresponding sub-pixels when displaying a white pixel;

FIG. 7 is diagram illustrating a method of switching on corresponding sub-pixels when a white vertical line is displayed according to an embodiment of the disclosure;

FIG. 8 is diagram illustrating a conventional method of switching on corresponding sub-pixels when displaying a white vertical line;

FIGS. 9a and 9b are diagrams respectively illustrating a method of switching on corresponding sub-pixels for color supplement rendering when a white vertical line is displayed according to embodiments of the disclosure;

FIGS. 10a and 10b are diagrams respectively illustrating a method of switching on corresponding sub-pixels when a red vertical line is displayed according to embodiments of the disclosure;

FIGS. 11a-11c are diagrams respectively illustrating a method of switching on corresponding sub-pixels for color supplement rending when a red vertical line is displayed according to embodiments of the disclosure;

FIG. 12 is a diagram illustrating a method of switching on corresponding sub-pixels when a red oblique line is displayed according to an embodiment of the disclosure; and

FIGS. 13a and 13b are diagrams respectively illustrating a method of switching on corresponding sub-pixels for color supplement rendering when a red oblique line is displayed according to an embodiment of the disclosure.

### DETAILED DESCRIPTION OF EMBODIMENTS

In the following, detailed implementations of a pixel structure, a method for driving the pixel structure and a display apparatus according to embodiments of the disclosure will be described in further detail with reference to drawings.

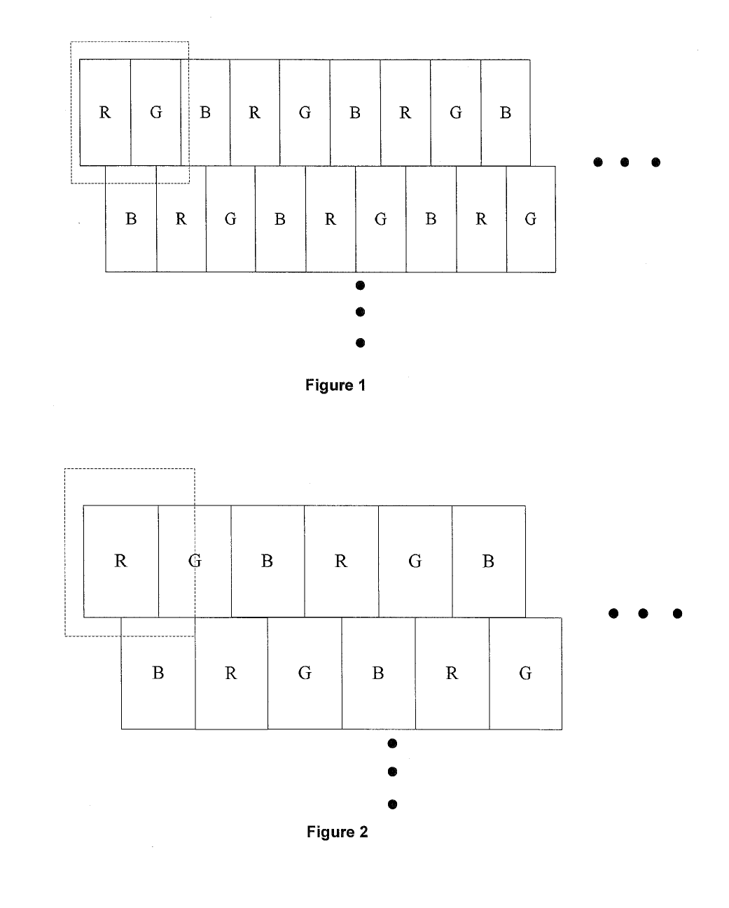

An embodiment of the disclosure provides a pixel structure. As illustrated in FIGS. 1-3, the pixel structure comprises a matrix of multiple R sub-pixels, G sub-pixels and B sub-pixels. In each row of the sub-pixels, at most two adjacent sub-pixels constitute a square pixel unit. Each two adjacent rows of the sub-pixels are offset relative to each other by half a sub-pixel along the row direction. Each of the sub-pixels is different in color from its adjacent sub-pixels. The multiple R, G, B sub-pixels may have the same shape.

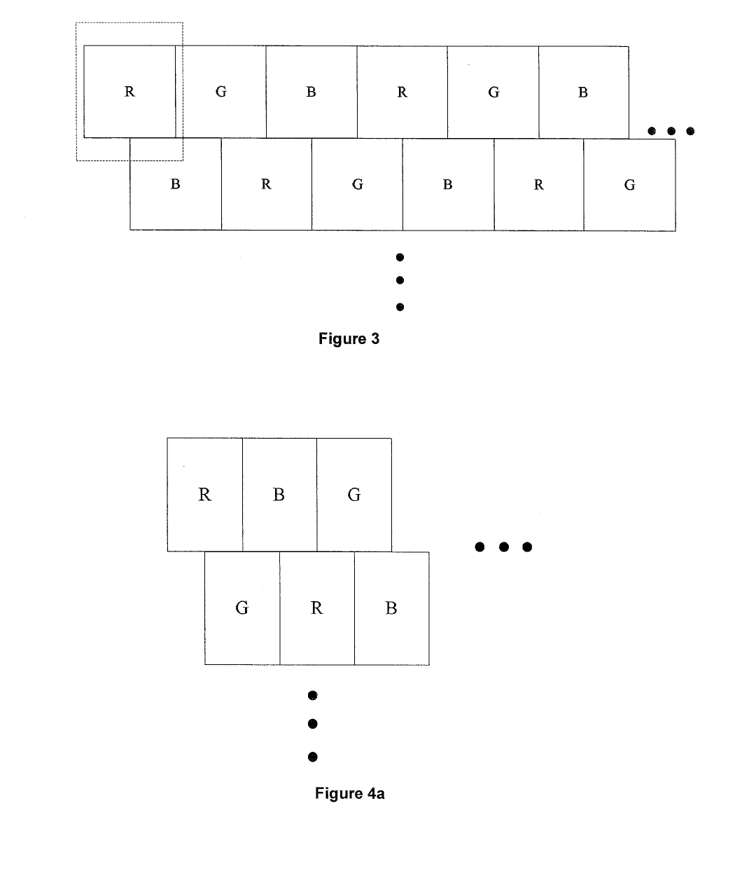

The above-described pixel structure according to the embodiment of the disclosure may comprise structures as shown in FIGS. 1-3. Specifically, as shown in FIG. 1, in each row of the sub-pixels, each two sub-pixels constitute a square pixel unit and each sub-pixel has a length-width ratio of 2:1. As shown in FIG. 2, in each row of the sub-pixels, each one and a half sub-pixel constitute a square pixel unit and each sub-pixel has a length-width ratio of 3:2. As shown in FIG. 3, in each row of the sub-pixels, each one sub-pixel constitutes a square pixel unit and each sub-pixel has a length-width ratio of 1:1. The pixel structure according to the embodiment of the disclosure may comprise at least one of the above three pixel structures, which is used with virtual calculation to realize virtual displaying. As such, it is possible to display the same information with fewer pixels by selectively switching on sub-pixels in a flexible manner without reducing the size of pixels, thereby increasing the output resolution for displayed images.

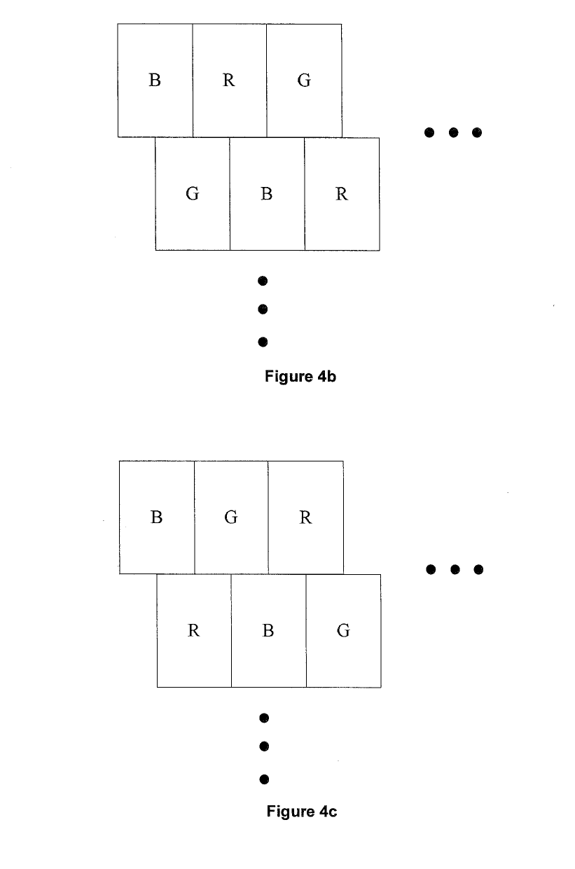

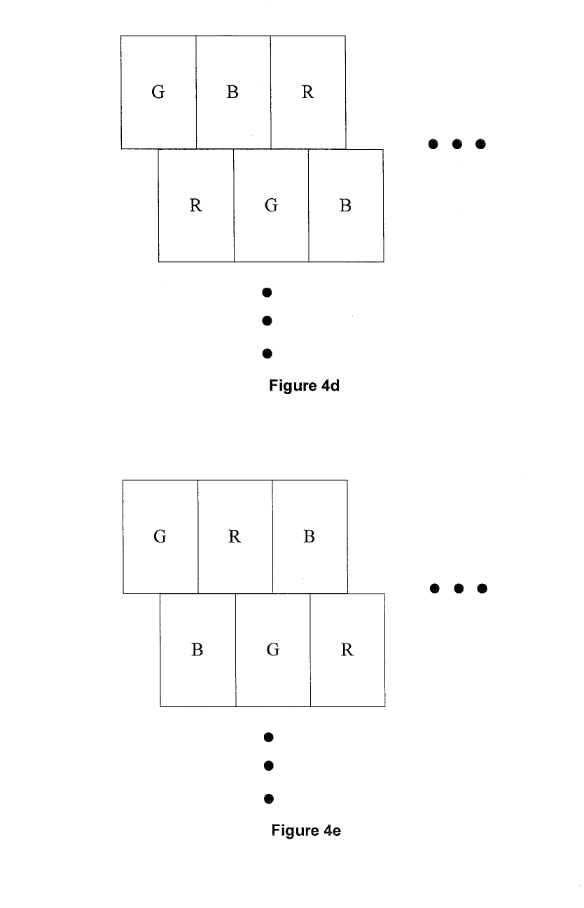

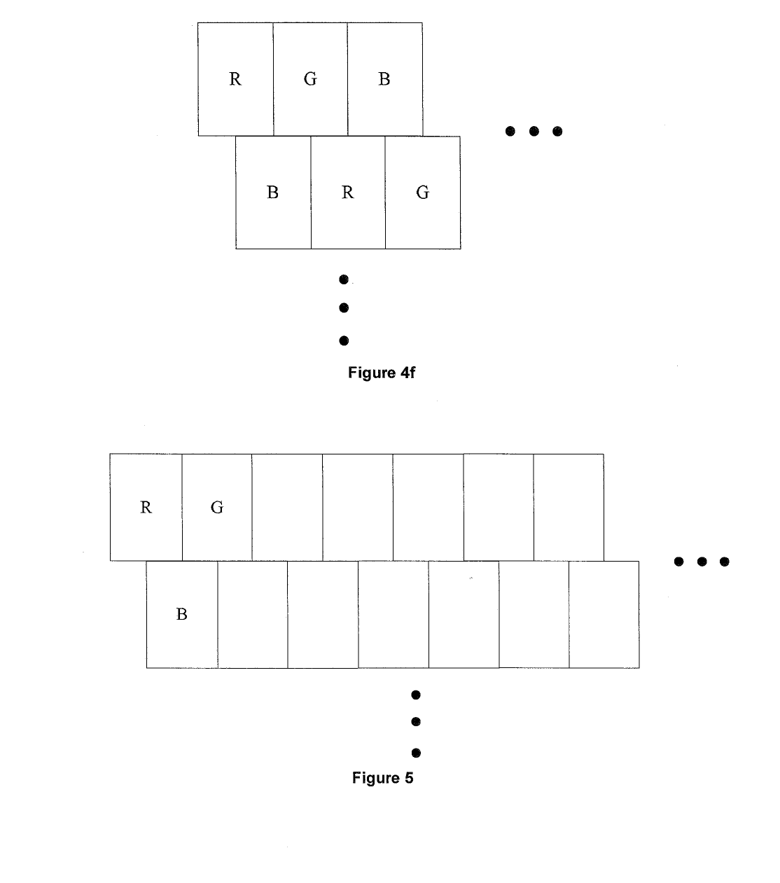

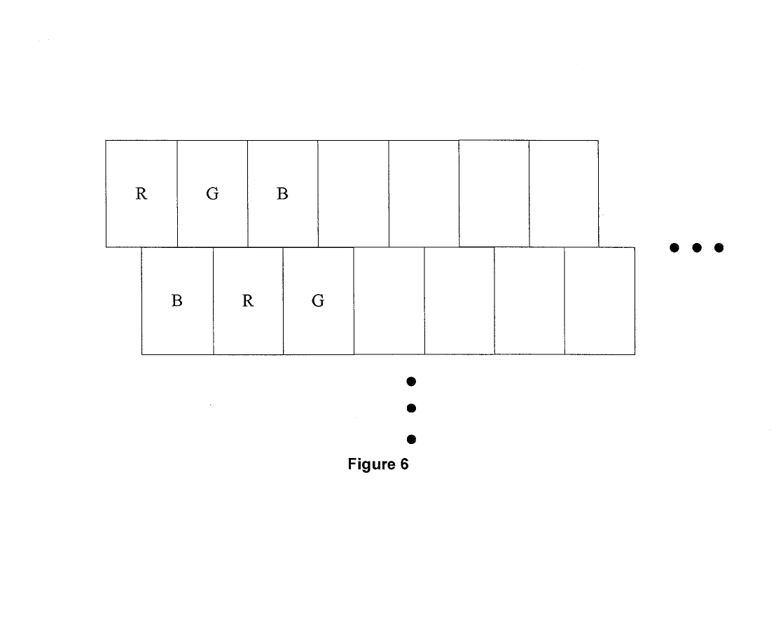

In detailed implementation, in the above-described pixel structure according to the embodiment of the disclosure, the multiple R, G, B sub-pixels are arranged in the matrix periodically by repeating a periodic unit of 3*2 sub-pixels. Specifically, in a case where each square pixel unit comprises 1.5 sub-pixels, the sub-pixels may be periodically arranged as shown in FIGS. 4a-4f. As shown in FIG. 4a, the 3*2 sub-pixels in the periodic unit may be [RBG, GRB]. As shown in FIG. 4b, the 3*2 sub-pixels in the periodic unit may be [BRG, GBR]. As shown in FIG. 4c, the 3*2 sub-pixels in the periodic unit may be [BGR, RBG]. As shown in FIG. 4d, the 3*2 sub-pixels in the periodic unit may be [GBR, RGB]. As shown in FIG. 4e, the 3*2 sub-pixels in the periodic unit may be [GRB, BGR]. As shown in FIG. 4f, the 3*2 sub-pixels in the periodic unit may be [RGB, BRG]. In addition, each two adjacent rows of the sub-pixels may be offset relative to each other by half a sub-pixel along the row direction. That is, even-numbered rows of sub-pixels are offset rightward by half a sub-pixel, or odd-numbered rows of sub-pixels are offset rightward by half a sub-pixel. The disclosure is not limited in this regard.

An embodiment of the disclosure provides a display apparatus, which comprises the above-described pixel structure according to the embodiment of the disclosure. The display apparatus may be used in any product or component with a display function, such as a handset, a tablet computer, a television, a monitor, a notebook computer, a digital photo frame, a navigator, etc. Since the display apparatus is similar to the pixel structure in their working principle, implementations of the above-described pixel structure may be used as reference for implementations of the display apparatus. Accordingly, no description will be given redundantly.

An embodiment of the disclosure provides a method for driving the above-described pixel structure according to the embodiment of the disclosure. The method comprises: upon receipt of an image signal for displaying at least a white pixel, switching on three adjacent sub-pixels triangularly arranged at a pixel unit in the pixel structure which displays the white pixel.

Specifically, according to the method for driving the above-described pixel structure according to the embodiment of the disclosure, the case where each square pixel unit comprises 1.5 sub-pixels is taken as an example. As shown in FIG. 5, when a white pixel is displayed, only three adjacent sub-pixels triangularly arranged at a pixel unit which displays the white pixel need to be switched on. As shown in FIG. 6, in the conventional pixel driving method, two adjacent groups of RGB sub-pixels in two adjacent rows at the pixel unit which displays the white pixel need to be switched on. Thus, the method for driving the pixel structure according to the embodiment of the disclosure allows the same information to be displayed with fewer pixels, thus increasing the output resolution for the displayed images.

In the above-described driving method according to the embodiment of the disclosure, when an image signal for displaying at least a row or column of white pixels is received, three adjacent sub-pixels triangularly arranged at each of pixel units in the pixel structure which display the row or column of white pixels are switched on.

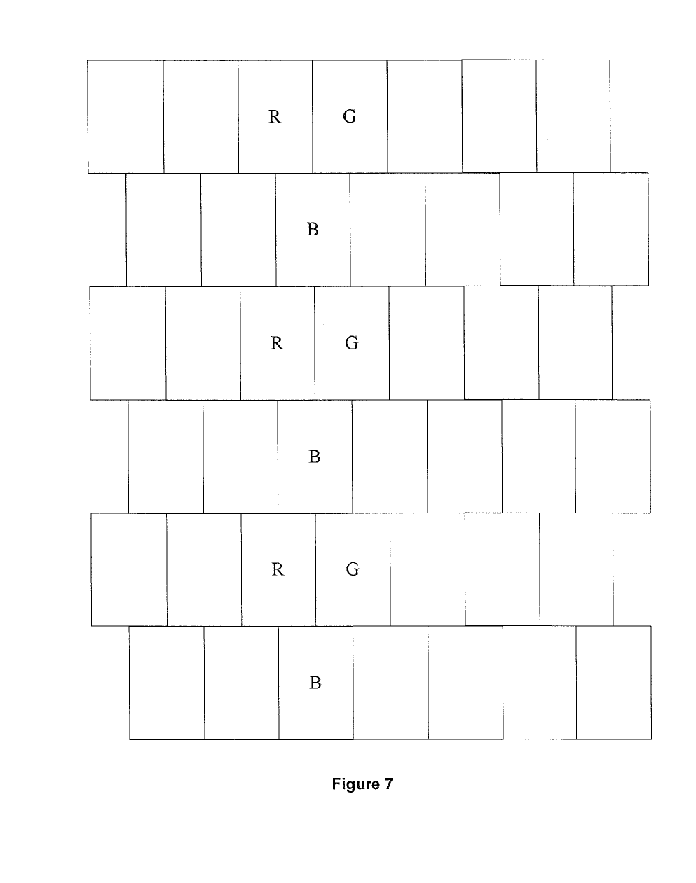

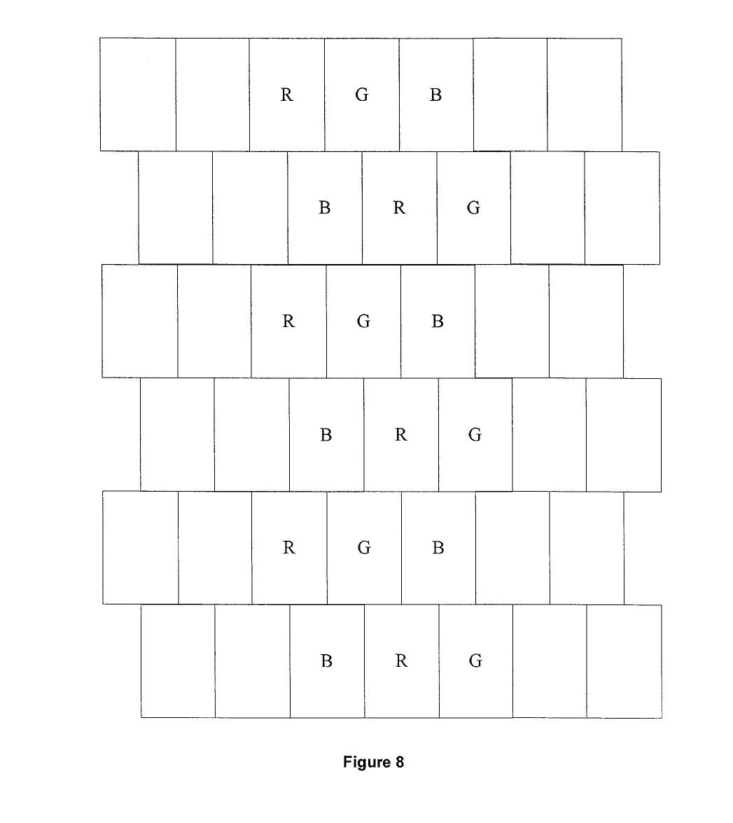

Specifically, as shown in FIG. 7, when a white vertical line is displayed, three adjacent sub-pixels triangularly arranged at each of pixel units which display the white vertical line are switched on for displaying the white vertical line. As shown in FIG. 8, in the prior art, when a white vertical line is displayed, a group of RGB sub-pixels in each row at each of pixel units which display the white vertical line need to be switched on. As two adjacent rows of sub-pixels have an offset of half a sub-pixel, the while vertical line displayed is not straight enough, thus leading to an unsatisfying displaying effect. In contrast, the method for driving the above-described pixel structure according to the embodiment of the disclosure allows corresponding sub-pixels to be selectively switched on in a flexible manner so that an RGB pixel group is formed by corresponding sub-pixels in adjacent rows, thus allowing the same information to be displayed with fewer pixels while improving the displaying effect.

The above-described driving method according to the embodiment of the disclosure may further comprise: switching on three adjacent sub-pixels triangularly arranged at each of one or two rows or columns of pixel units in the pixel structure which are adjacent to the pixel units which display the row or the column of white pixels.

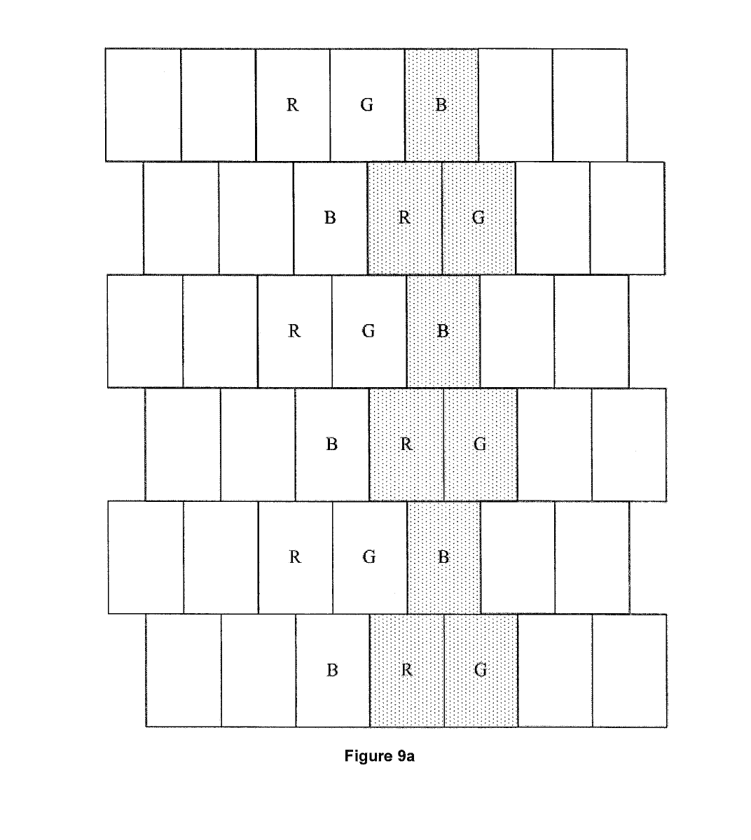

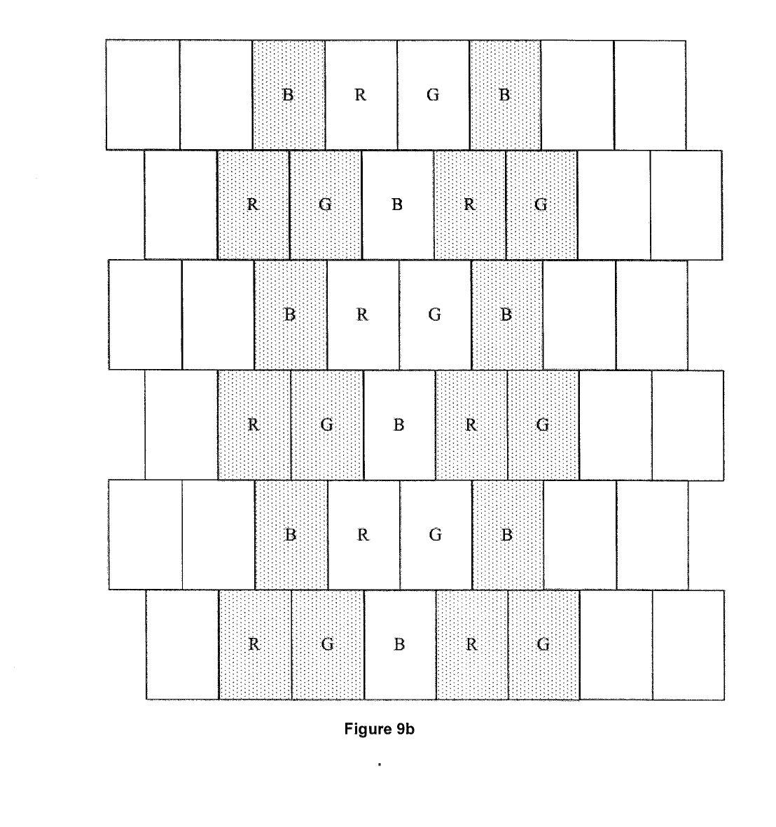

Specifically, as shown in FIG. 9a, when a white vertical line is displayed, three adjacent sub-pixels triangularly arranged at each of a column of pixel units which are at the right side of the white vertical line are switched on in order to supplement the color of the white vertical line. As such, the displaying of the white vertical line can give a sense of multilayer, the displaying effect is improved, and the displayed image is clearer. Alternatively, as shown in FIG. 9b, three adjacent sub-pixels triangularly arranged at each of a column of pixel units which are at both sides of the white vertical line are switched on. As such, the grayscale of white vertical line can be adjusted and the display effect is improved.

In the above-described driving method according to the embodiment of the disclosure, when an image signal for displaying at least a pixel of a single color is received, a sub-pixel of the same color at a pixel unit in the pixel structure which displays the pixel of the single color is switched on.

In the above-described driving method according to the embodiment of the disclosure, when an image signal for displaying at least a row or column of pixels of a single color is received, a sub-pixel of the same color at each of pixel units in the pixel structure which display the row or column of pixels of the single color is switched on.

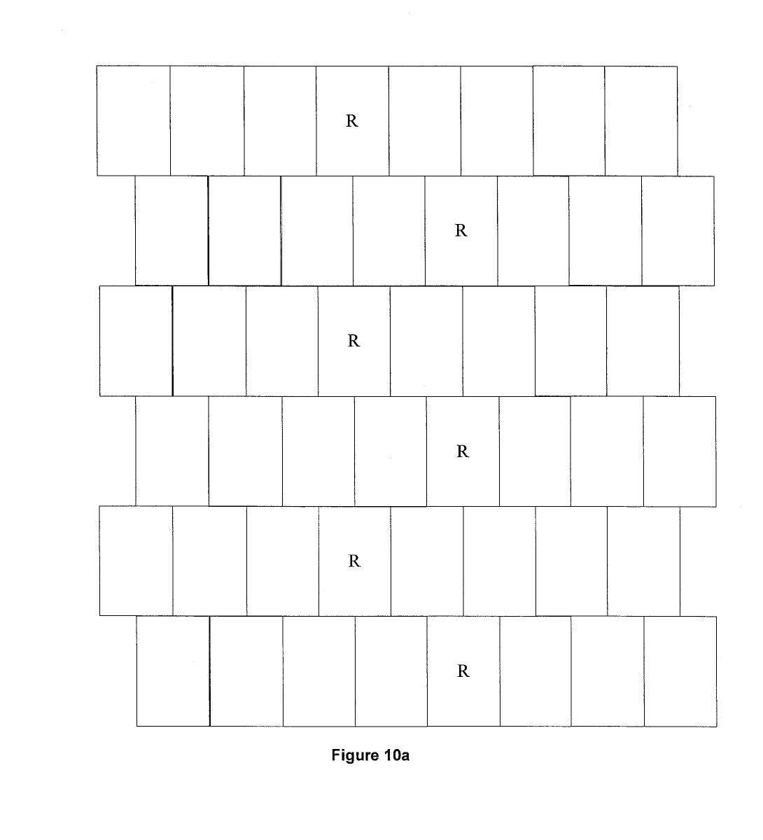

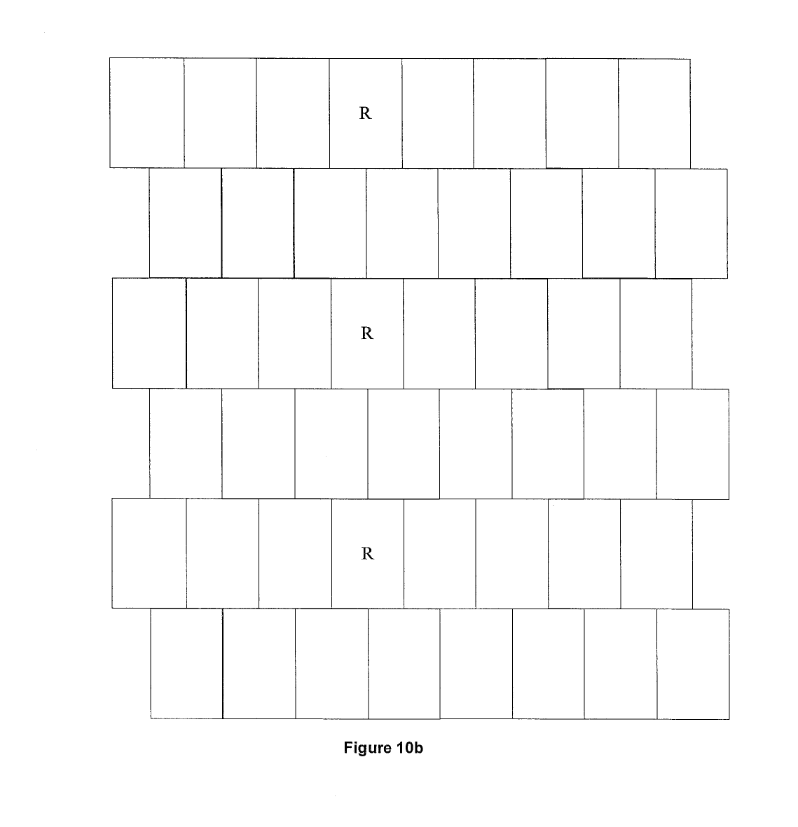

Specifically, as shown in FIG. 10a, when a red vertical line is displayed, two columns of red sub-pixels at pixel units which display the red vertical line are switched on. The red vertical line thus displayed is brighter and looks clearer. According to the embodiment of the disclosure, when a fine line of a single color (for example, a red fine line) is displayed with high resolution, a column of red sub-pixels at pixel units which display the red fine line are switched on, as shown in FIG. 10b. With one sub-pixel in every two adjacent lines being switched on, the red fine line looks thinner macroscopically and the displaying effect is improved.

The above-described driving method according to the embodiment of the disclosure may further comprise: switching on a sub-pixel of the same color at each of one or two rows or columns of pixel units in the pixel structure which are adjacent to the pixel units that display the row or the column of pixels of the single color.

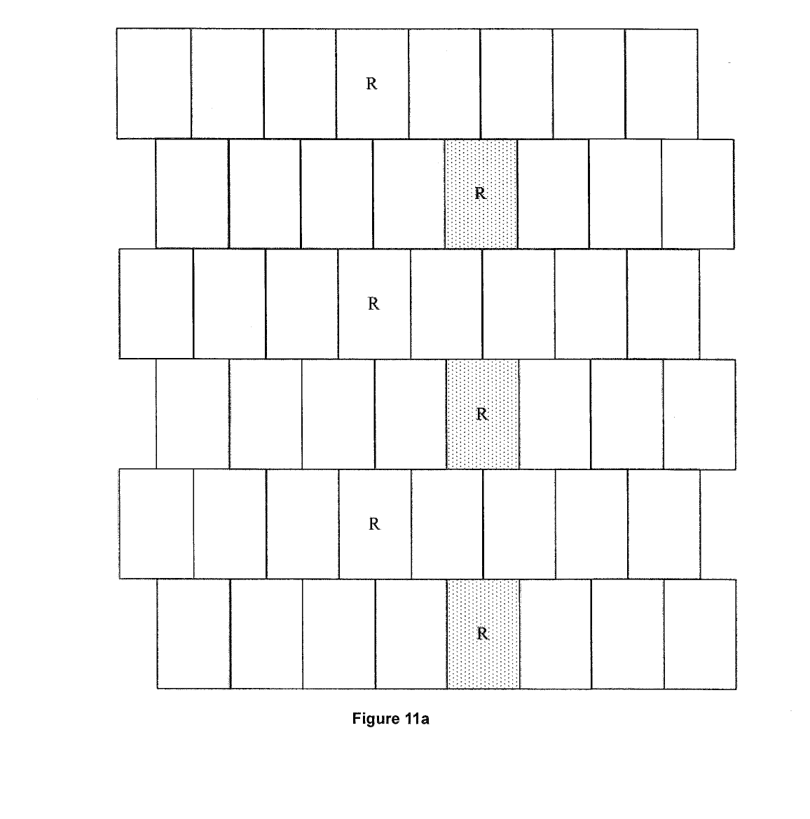

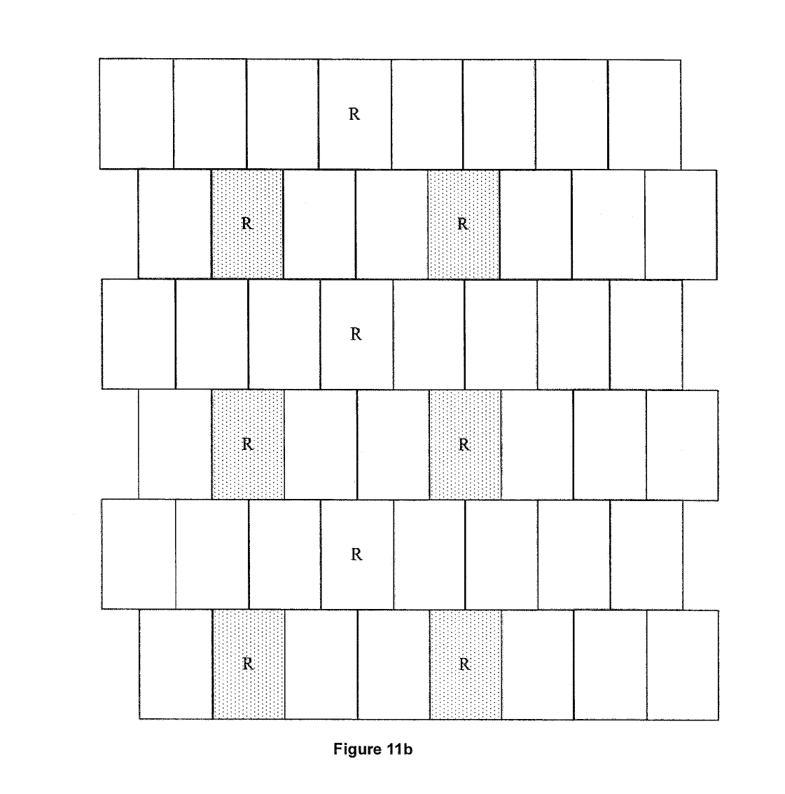

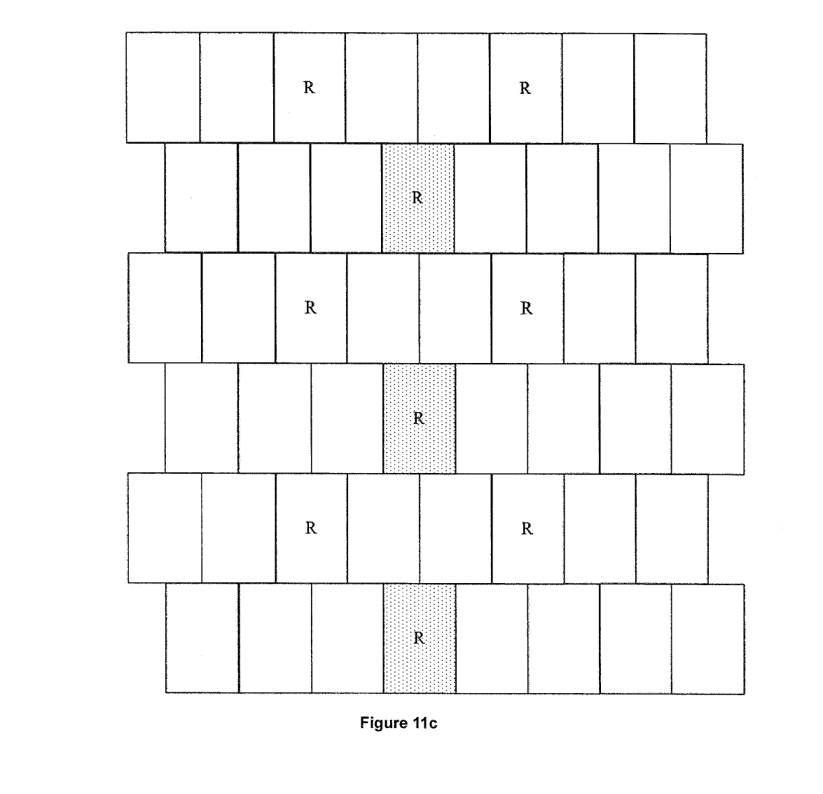

Specifically, when a red vertical line is displayed, a column of red sub-pixels at one side of the red vertical line may be switched on as shown in FIG. 11a, or red sub-pixels at both sides of the red vertical line may be switched on as shown in FIG. 11b. As such, it is possible to perform color supplement rendering for the displayed red vertical line, thereby making the displayed red vertical line more clear and thus improving the displaying effect. In addition, when two red vertical lines are displayed and they are close to each other, a column of red sub-pixels between them may be switched on so as to highlight the two red vertical lines displayed, thereby making the two red vertical lines exhibit directionality and thus improving the visual resolution.

The above-described driving method according to the embodiment of the disclosure, when an image signal for displaying at least an oblique line of pixels of a single color is received, a sub-pixel of the same color at each of pixel units in the pixel structure which display the oblique line of pixels of the single color is switched on, and/or

a sub-pixel of the same color at each of one or two oblique lines of pixel units in the pixel structure which are parallel to and adjacent to the oblique line of the single color on one or both sides is switched on.

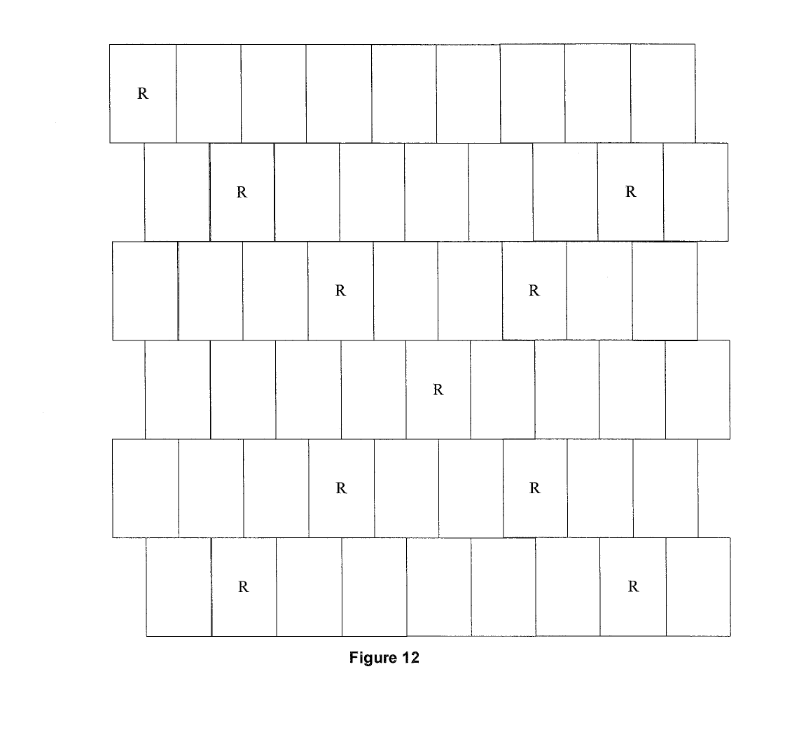

Specifically, in the above-described driving method according to the embodiment of the disclosure, when an oblique line of a single color (for example, a red diagonal line inclined at an angle of 45 degrees) is displayed, red sub-pixels corresponding to the red diagonal line are switched on as shown in FIG. 12. With the even-numbered rows of sub-pixels being offset by half a sub-pixel, the red diagonal line inclined at an angle of 45 degrees looks clearer and the visual resolution is improved.

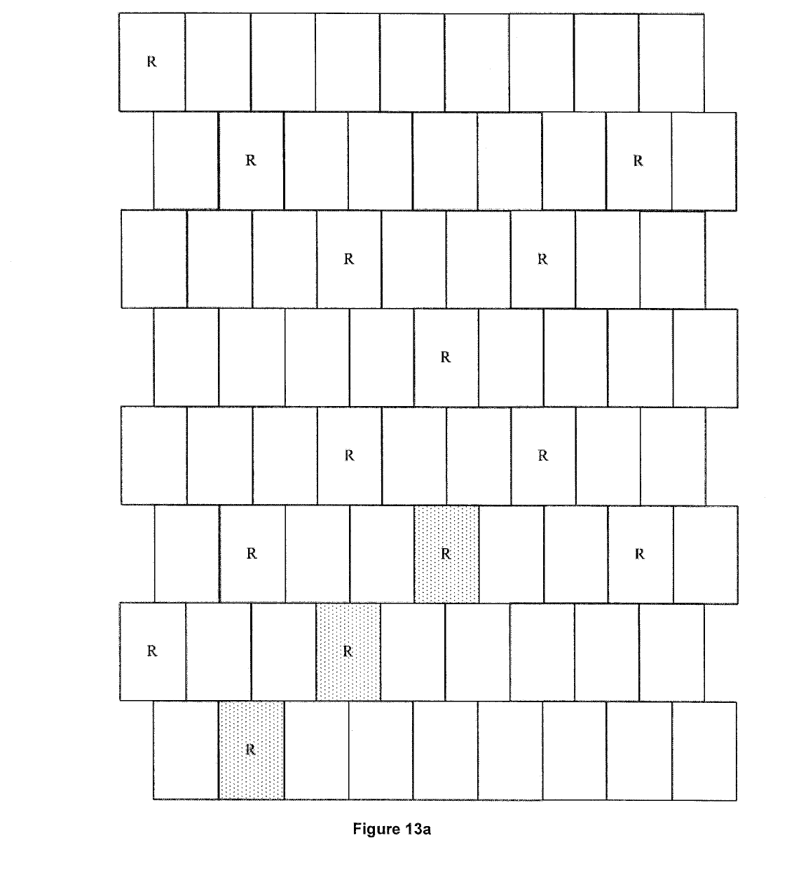

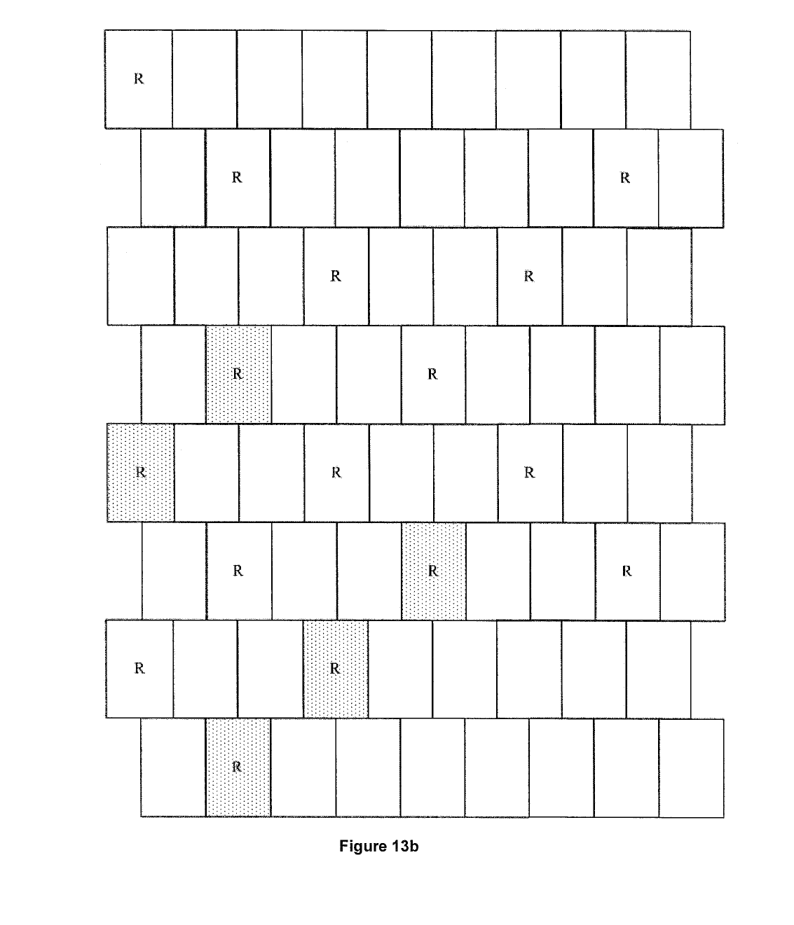

Specifically, in the above-described driving method according to the embodiment of the disclosure, when oblique line(s) of a single color (for example, two crossed red diagonal lines each inclined at an angle of 45 degrees) are displayed, red sub-pixels at pixel units which are parallel to one of the two red diagonal lines may be switched on, as shown in FIG. 13a, in order to highlight the displayed red diagonal line can be highlighted and improve the expressiveness thereof. Alternatively, as shown in FIG. 13b, red sub-pixels at pixel units which are parallel to and at both sides of one of the two red diagonal lines may be switched on. Likewise, the displayed red diagonal line can be highlighted and the expressiveness thereof is improved.

Obviously, those skilled in the art can make various alterations and changes to the disclosure without departing from the spirit and scope thereof. Thus, if these alterations and changes fall within the scope of the claims and the technical equivalents thereof, they are intended to be covered by the disclosure.

What is claimed is:

1. A pixel structure comprising a matrix of multiple R sub-pixels, G sub-pixels and B sub-pixels, wherein
in each row of the sub-pixels, at most two adjacent sub-pixels constitute a square pixel unit,
each two adjacent rows of the sub-pixels are offset relative to each other by half a sub-pixel along a row direction,
each of the sub-pixels is different in color from its adjacent sub-pixels.

2. The pixel structure according to claim 1, wherein in each row of the sub-pixels,
each two sub-pixels constitute a square pixel unit and each sub-pixel has a length-width ratio of 2:1,
each one and a half sub-pixels constitute a square pixel unit and each sub-pixel has a length-width ratio of 3:2, or
each one sub-pixel constitutes a square pixel unit and each sub-pixel has a length-width ratio of 1:1.

3. A display apparatus comprising a pixel structure according to claim 1.

4. A display apparatus comprising a pixel structure according to claim 2.

5. A method for driving a pixel structure according to claim 1, the method comprising:
upon receipt of an image signal for displaying at least a white pixel, switching on three adjacent sub-pixels triangularly arranged at a pixel unit in the pixel structure which displays the white pixel.

6. A method for driving a pixel structure according to claim 2, the method comprising:
upon receipt of an image signal for displaying at least a white pixel, switching on three adjacent sub-pixels triangularly arranged at a pixel unit in the pixel structure which displays the white pixel.

7. The method according to claim 5, wherein
upon receipt of an image signal for displaying at least a row or column of white pixels, switching on three adjacent sub-pixels triangularly arranged at each of pixel units in the pixel structure which display the row or column of white pixels.

8. The method according to claim 7, further comprising:
switching on three adjacent sub-pixels triangularly arranged at each of one or two rows or columns of pixel units in the pixel structure which are adjacent to the pixel units which display the row or the column of white pixels.

9. The method according to claim 7, wherein
upon receipt of an image signal for displaying at least a pixel of a single color, switching on a sub-pixel of the same color at a pixel unit in the pixel structure which displays the pixel of the single color.

10. The method according to claim 7, wherein
upon receipt of an image signal for displaying at least a row or column of pixels of a single color, switching on a sub-pixel of the same color at each of pixel units in the pixel structure which display the row or column of pixels of the single color.

11. The method according to claim 10, further comprising:
switching on a sub-pixel of the same color at each of one or two rows or columns of pixel units in the pixel structure which are adjacent to the pixel units that display the row or the column of pixels of the single color.

12. The method according to claim 7, wherein
upon receipt of an image signal for displaying at least an oblique line of pixels of a single color, switching on a sub-pixel of the same color at each of pixel units in the pixel structure which display the oblique line of pixels of the single color.

13. The method according to claim 7, wherein
upon receipt of an image signal for displaying at least an oblique line of pixels of a single color, switching on a sub-pixel of the same color at each of one or two oblique lines of pixel units in the pixel structure which are parallel to and adjacent to the oblique line of the single color on one or both sides.

14. The method according to claim 12, further comprising switching on a sub-pixel of the same color at each of one or two oblique lines of pixel units in the pixel structure which are parallel to and adjacent to the oblique line of the single color on one or both sides.
